(19) United States
(12) Patent Application Publication
(10) Pub. No.: US 2019/0003054 A1
(43) Pub. Date: Jan. 3, 2019

(54) VAPOR DEPOSITION APPARATUS

(71) Applicant: WUHAN CHINA STAR OPTOELECTRONICS TECHNOLOGY CO., LTD., Wuhan, Hubei (CN)

(72) Inventor: Fengju Liu, Wuhan, Hebei (CN)

(21) Appl. No.: 15/569,671

(22) PCT Filed: Jul. 12, 2017
(86) PCT No.: PCT/CN2017/092660

§ 371 Date: Oct. 26, 2017

(30) Foreign Application Priority Data
Jun. 28, 2017 (CN) 201710505502.3

(51) Int. Cl. C23C 16/509

(52) U.S. Cl. CPC C23C 16/509

(57) ABSTRACT

The present disclosure discloses a vapor deposition apparatus, including a cavity, a first electrode, a second electrode and a gas feed tube. The cavity is provided with a gas inlet and a gas outlet thereon. The first electrode and the second electrode are disposed in the cavity. The first electrode is connected to a high frequency alternating power and the second electrode is grounded. The first electrode is disposed at a side where the gas inlet is located, and the second electrode is disposed to be parallel with and opposite to the first electrode. The first electrode includes a first opening facing the gas inlet and a second opening opposite to the gas inlet and connected with the first opening. The gas feed tube is introduced from the gas inlet and connected to the first opening.

### BACKGROUND OF THE INVENTION

### 1. Field of the Invention

The present disclosure relates to a technical field of vapor deposition evaporation, and particularly, to a vapor deposition apparatus.

### 2. The Related Arts

PECVD (Plasma Enhanced Chemical Vapor Deposition) enhances chemical activity of a reaction site and promotes chemical reaction between gases by means of low temperature plasma generated by gas glow discharge, so that a solid film may also be formed on a substrate at a low temperature. The PECVD is widely applied in semiconductor and flat panel display industries, and especially, in LTPS and OLED flat panel display industries. A PECVD apparatus is an indispensable and key apparatus, which is used to prepare SiNₓ, SiOₓ and α-Si (Amorphous silicon) thin films, and solid film products thereof may be applied on a variety of soft substrates and hard substrates.

The PECVD apparatus generally generates the plasma through opposite discharge of one or several pairs of electrode rollers. A discharge region forms a discharge area between two sets of electrodes. Electrons generated by the discharge in the discharge region collide with molecules or atoms to generate the plasma. The chemical reaction of reaction gas is promoted to form new component particles in a high energy plasma motion process. The new component particles form a regular motion under the control of a magnetic field, and are eventually deposited on an outer wall of the substrate or the apparatus to form the solid thin film.

In the actual PECVD process, a processing cavity of the apparatus is fixed with a nozzle for spraying gas therein, a gas feed tube connected with a gas source is connected to the nozzle, and the gas sprayed by the nozzle is dissociated to form the plasma between the electrodes. However, it is not convenient to fix the nozzle between the electrodes, and a volume of the apparatus is also increased.

### SUMMARY

In view of the shortcomings in the prior art, the present disclosure provides a vapor deposition apparatus, which may reduce the number of components and the volume of the apparatus.

In order to achieve the above purpose, the present disclosure adopts the following technical solution.

A vapor deposition apparatus includes a cavity, a first electrode, a second electrode and a gas feed tube, wherein the cavity is provided with a gas inlet and a gas outlet thereon; the first electrode and the second electrode are disposed in the cavity, and the first electrode is connected to a high frequency alternating power and the second electrode is grounded; the first electrode is disposed at a side where the gas inlet is located, and the second electrode is disposed to be parallel with and opposite to the first electrode; the first electrode comprises a first opening facing the gas inlet and a second opening opposite to the gas inlet and connected with the first opening; and the gas feed tube is introduced from the gas inlet and connected to the first opening.

As one of the implementations, an inner of the first electrode is hollowed to form a cavity structure, and the first opening and the second opening are disposed on two opposite surfaces of the cavity structure, respectively, the second opening being in plural and disposed in an array.

As one of the implementations, the gas feed tube and the first electrode are disposed to be insulated from each other.

As one of the implementations, an insulating connecting ring is connected between the gas feed tube and the first opening, and the connecting ring is positioned in the cavity.

As one of the implementations, an outer surface of the connecting ring is covered with a first water cooling pipe.

Or, the gas feed tube is made of an insulating material.

As one of the implementations, an outer surface of the gas feed tube is covered with a second water cooling pipe.

As one of the implementations, the gas outlet of the vacuum cavity is positioned at a side where the second electrode is located.

As one of the implementations, the first electrode is provided with at least one layer of filter screen therein.

As one of the implementations, the vapor deposition apparatus further includes a toroidal ferromagnet provided to cover an outer wall of the gas feed tube.

The first electrode of the present disclosure has the first opening connected with the gas feed tube and the second opening for spraying the gas thereon. The incoming gas may be sprayed toward a gap between the first electrode and the second electrode by externally connecting the first electrode to the high frequency alternating power. Thus, it is not necessary to additionally dispose a nozzle, which reduces the number of components and also reduces the volume of the apparatus.

### BRIEF DESCRIPTION OF THE DRAWINGS

FIG. 1 is a structural schematic diagram of the vapor deposition apparatus according to Embodiment 1 of the present disclosure;

FIG. 2 is a structural schematic diagram of the vapor deposition apparatus according to Embodiment 2 of the present disclosure; and

FIG. 3 is a structural schematic diagram of the vapor deposition apparatus according to Embodiment 3 of the present disclosure.

### DETAILED DESCRIPTION OF THE PREFERRED EMBODIMENTS

In order to make the purpose, technical solution and advantages of the present disclosure clearer, the present disclosure is further described in details below in conjunction with the drawings and the embodiments. It should be understood that the specific embodiments described here are only used to explain the present disclosure, but are not used to limit the present disclosure.

### Embodiment 1

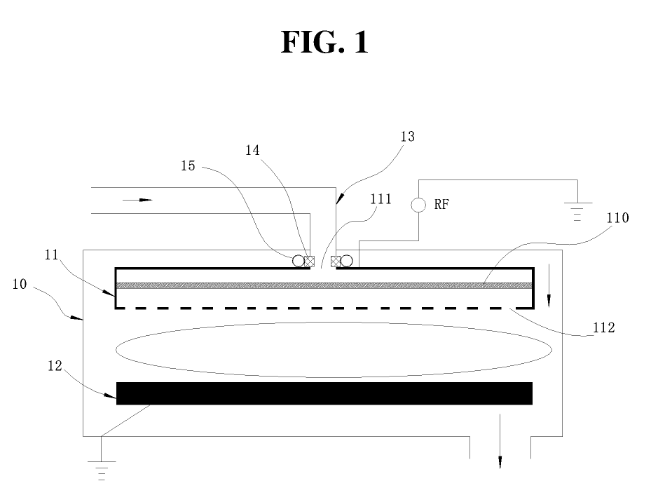

Referring to FIG. 1, the PECVD vapor deposition apparatus of the present embodiment mainly includes a cavity 10, a first electrode 11, a second electrode 12 and a gas feed tube 13. The cavity 10 is provided with a gas inlet and a gas outlet thereon. The first electrode 11 and the second electrode 12 both are disposed in the cavity 10, and the first electrode 11 is connected to a high frequency alternating power (RF Power) and the second electrode 12 is grounded. The first electrode 11 is disposed at a side where the gas inlet is located, and the second electrode 12 is disposed to be parallel with and opposite to the first electrode 11. The first electrode 11 has a first opening 111 facing the gas inlet and a second opening 112 opposite to the gas inlet and connected with the first opening 111. The gas feed tube 13 is introduced from the gas inlet and connected to the first opening 111.

Here, after the gas feed tube 13 is inserted into the gas inlet, the gas inlet is sealed to ensure that the gas in the cavity 10 is not accidentally leaked. An inner of the first electrode 11 is hollowed to form a cavity structure. The first opening 111 and the second opening 112 are disposed on two opposite surfaces of the cavity structure, respectively. The second opening 112 is in plural and disposed in a surface of the first electrode 11 in an array. The gas provided by a gas source is introduced through the gas feed tube 13, and sprayed from the second opening 112 after passing through the first opening 111 of the first electrode 11 and the cavity structure within the first electrode 11 in order; the high frequency alternating power is applied to the first electrode 11 in the upper part and the second electrode 12 is grounded. The gas is dissociated to form the plasma in the gap between the two electrodes. A length of the second electrode 12 is preferably equal to or longer than that of the first electrode 11, so that the gas sprayed from the first electrode 11 is sufficiently plasma zed.

The gas outlet of the vacuum cavity 10 of the present embodiment is positioned at a side where the second electrode 12 is located. The plasma may be accelerated by a sucking pump to be discharged into apparatuses in the subsequent process. The cavity 10 is also grounded, so as to avoid affecting the plasma process. In addition, the gas feed tube 13 and the first electrode 11 are disposed to be insulated from each other; and an insulating connecting ring 14 is connected between the gas feed tube 13 and the first opening 111, and the connecting ring 14 is positioned in the cavity 10. The high frequency alternating power cannot enter into the gas feed tube 13, which avoids the generation of parasitic plasma to the maximum, so as to avoid evaporation defects caused by the parasitic plasma generated by the gas feed tube and improve a yield of the substrate.

Even if a phenomenon of generating the parasitic plasma is improved by improving the gas feed tube 13 in the present embodiment, the parasitic plasma may be formed in the gas feed tube due to various unknown reasons. A loose thin film or a granular material (for example, SiH₄ is dissociated to generate a Si particle) may be formed at a part where the parasitic plasma is generated. The thin film or the granular material falls onto the substrate after being blown into the cavity of the first electrode 11 by the gas, which may cause the film formed on the substrate to have a large number of defects and have great effect on the yield of the product. In order to further resolve the problem, the first electrode 11 may be further provided with at least one layer of filter screen 110 therein. The filter screen 110 stretches across the cavity of the first electrode 11, and separates the cavity of the first electrode 11 into upper and lower portions as shown in FIG. 1. Even if the parasitic plasma causes the formation of the thin film or the granular material, the filter screen 110 may prevent the thin film or the granular material from further passing through the second opening 112.

In order to prevent a connection between the gas feed tube 13 and the first electrode 11 from being disconnected due to an excessively high temperature at the connection portion, an outer surface of the connecting ring 14 of the present embodiment is further covered with a first water cooling pipe 15. A good connecting state at the connection portion can be secured by continuously supplying coolant to the first water cooling pipe 15.

### Embodiment 2

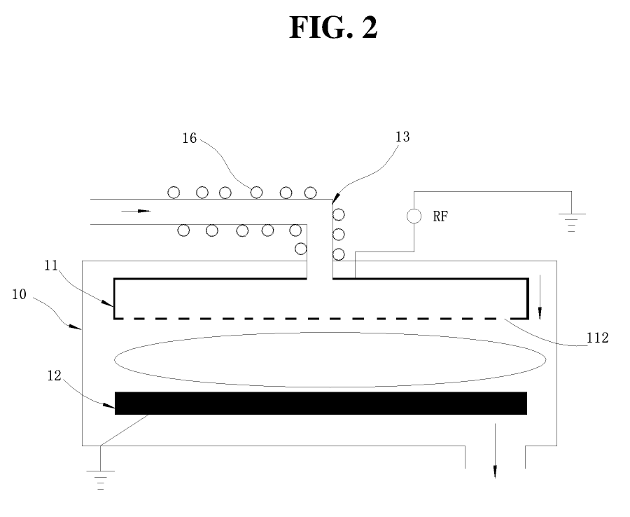

As shown in FIG. 2, different from Embodiment 1, the whole gas feed tube 13 of the present embodiment is made of an insulating material; and an outer surface of the gas feed tube 13 is covered with a second water cooling pipe 16 to cool the gas feed tube 13, which prevents the high frequency alternating power on the first electrode 11 from entering into the gas feed tube 13 to the maximum, so as to greatly improve the reliability.

### Embodiment 3

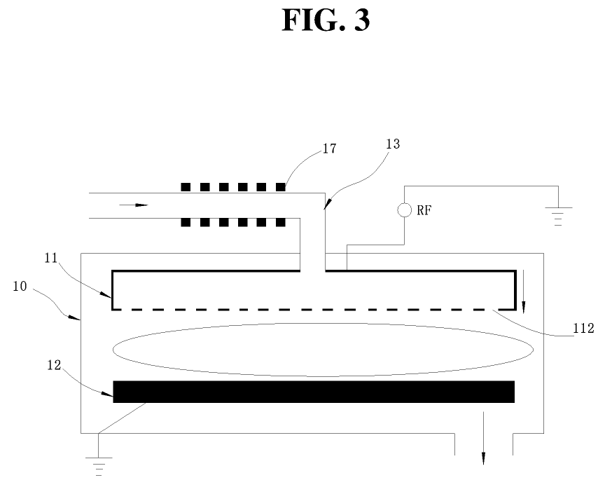

As shown in FIG. 3, different from Embodiments 1 and 2, the PECVD vapor deposition apparatus of the present embodiment further has a toroidal (or spiral) ferromagnet 17. The ferromagnet 17 is provided to cover an outer wall of the gas feed tube 13. Even if the gas feed tube 13 is made of a conductive material, the high frequency alternating power may encounter a great magnetic resistance when entering into a region where the ferromagnet 17 is located, which may also prevent a parasitic plasma from being generated at an insulating connection portion where the high frequency alternating power leaks onto the gas feed tube 13.

The first electrode of the present disclosure has the first opening connected with the gas feed tube and the second opening for spraying the gas thereon. The incoming gas may be sprayed toward a gap between the first electrode and the second electrode by externally connecting the first electrode to the high frequency alternating power. Thus, it is not necessary to additionally dispose a nozzle, which reduces the number of components and also reduces the volume of the apparatus. Meanwhile, the evaporation defects caused by the parasitic plasma generated by the gas feed tube may be further prevented to improve the yield of the substrate.

The above descriptions are only the specific embodiments of the present application, it should be pointed out that to those ordinarily skilled in the technical art, several improvements and modifications may be further made without departing from the principle of the present application, and these improvements and modifications should also be considered as the protection scope of the present application.

What is claimed is:

1. A vapor deposition apparatus, comprising a cavity, a first electrode, a second electrode and a gas feed tube, wherein the cavity is provided with a gas inlet and a gas outlet thereon; the first electrode and the second electrode are disposed in the cavity, and the first electrode is connected to a high frequency alternating power and the second electrode is grounded; the first electrode is disposed at a side where the gas inlet is located, and the second electrode is disposed to be parallel with and opposite to the first electrode; the first electrode comprises a first opening facing the gas inlet and a second opening opposite to the gas inlet and connected with the first opening; and the gas feed tube is introduced from the gas inlet and connected to the first opening.

2. The vapor deposition apparatus of claim 1, wherein, the vapor deposition apparatus further comprising a toroidal ferromagnet provided to cover an outer wall of the gas feed tube.

3. The vapor deposition apparatus of claim 1, wherein an inner of the first electrode is hollowed to form a cavity structure, and the first opening and the second opening are disposed on two opposite surfaces of the cavity structure, respectively, the second opening being in plural and disposed in an array.

4. The vapor deposition apparatus of claim 3, wherein, the vapor deposition apparatus further comprising a toroidal ferromagnet provided to cover an outer wall of the gas feed tube.

5. The vapor deposition apparatus of claim 3, wherein the gas feed tube and the first electrode are disposed to be insulated from each other.

6. The vapor deposition apparatus of claim 5, wherein, the vapor deposition apparatus further comprising a toroidal ferromagnet provided to cover an outer wall of the gas feed tube.

7. The vapor deposition apparatus of claim 5, wherein an insulating connecting ring is connected between the gas feed tube and the first opening, and the connecting ring is positioned in the cavity.

8. The vapor deposition apparatus of claim 7, wherein, the vapor deposition apparatus further comprising a toroidal ferromagnet provided to cover an outer wall of the gas feed tube.

9. The vapor deposition apparatus of claim 7, wherein an outer surface of the connecting ring is covered with a first water cooling pipe.

10. The vapor deposition apparatus of claim 9, wherein, the vapor deposition apparatus further comprising a toroidal ferromagnet provided to cover an outer wall of the gas feed tube.

11. The vapor deposition apparatus of claim 5, wherein the gas feed tube is made of an insulating material.

12. The vapor deposition apparatus of claim 11, wherein, the vapor deposition apparatus further comprising a toroidal ferromagnet provided to cover an outer wall of the gas feed tube.

13. The vapor deposition apparatus of claim 11, wherein an outer surface of the gas feed tube is covered with a second water cooling pipe.

14. The vapor deposition apparatus of claim 13, wherein, the vapor deposition apparatus further comprising a toroidal ferromagnet provided to cover an outer wall of the gas feed tube.

15. The vapor deposition apparatus of claim 3, wherein the gas outlet of the vacuum cavity is positioned at a side where the second electrode is located.

16. The vapor deposition apparatus of claim 15, wherein, the vapor deposition apparatus further comprising a toroidal ferromagnet provided to cover an outer wall of the gas feed tube.

17. The vapor deposition apparatus of claim 3, wherein the first electrode is provided with at least one layer of filter screen therein.

18. The vapor deposition apparatus of claim 17, wherein, the vapor deposition apparatus further comprising a toroidal ferromagnet provided to cover an outer wall of the gas feed tube.

19. A vapor deposition apparatus, comprising a cavity, a first electrode, a second electrode and a gas feed tube, wherein the cavity is provided with a gas inlet and a gas outlet thereon, the first electrode and the second electrode are disposed in the cavity, the first electrode is connected to a high frequency alternating power and the second electrode is grounded, the cavity is grounded, the first electrode is disposed at a side where the gas inlet is located, the second electrode is disposed to be parallel with and opposite to the first electrode, and the first electrode is provided with at least one layer of filter screen therein; the first electrode comprises a first opening facing the gas inlet and a second opening opposite to the gas inlet and connected with the first opening, and the gas feed tube is introduced from the gas inlet and connected to the first opening.
